(19) United States
(12) Patent Application Publication
(10) Pub. No.: US 2015/0006806 A1
(43) Pub. Date: Jan. 1, 2015

(54) DOUBLE DATA RATE SYNCHRONOUS DYNAMIC RANDOM ACCESS MEMORY MODULE AND CONFIGURING METHOD THEREOF

(71) Applicant: Electronics and Telecommunications Research Institute, Daejeon (KR)

(72) Inventors: Hyuk-Je Kwon, Daejeon (KR); Young-Seok Choi, Daejeon (KR); Sung-Nam Kim, Daejeon (KR); Gyung-Ock Kim, Daejeon (KR)

(73) Assignee: Electronics and Telecommunications Research Institute, Daejeon (KR)

(21) Appl. No.: 14/244,047

(22) Filed: Apr. 3, 2014

(30) Foreign Application Priority Data
Jun. 26, 2013 (KR) 10-2013-0073985

(51) Int. Cl. G11C 7/10

(52) U.S. Cl. CPC G11C 7/1072
USPC 711/106

(57) ABSTRACT

Disclosed are a double data rate synchronous dynamic random access memory module and a configuring method thereof. The DDR SDRAM module in accordance with an embodiment of the present invention includes: a plurality of memory chips; and a serial transceiver portion configured to serially receive first serial data including a control signal and data transferred from outside for the plurality of memory chips and to provide the control signal and the data included in the serially received first serial data to the plurality of memory chips.

### CROSS-REFERENCE TO RELATED APPLICATIONS

This application claims the benefit of Korean Patent Application No. 10-2013-0073985, filed with the Korean Intellectual Property Office on Jun. 26, 2013, the disclosure of which is incorporated herein by reference in its entirety.

### BACKGROUND

1. Technical Field

The present invention relates to a DDR SDRAM (double data rate synchronous dynamic random access memory) module, more specifically to a DDR SDRAM module and a method for configuring the same to reduce a data bus width of the DDR SDRAM and perform high speed serial communication.

2. Background Art

Generally, the DDR SDRAM consists of data buses, control buses and power lines, and the number of DDR memory devices, which is usually 2 or 4, in a PC's main board is determined by the number of memory channels that a CPU can support. The DDR SDRAM is inserted into a dual in-line memory module (DIMM) socket. The DIMM has 186˜240 pins, and thus in case there are 2 memory channels supported by the CPU, 372˜480 signal lines and power lines should be assigned, disposed, and connected with other elements in the main board. A conventional DDR SDRAM communicates with the CPU by being inserted in the DIMM socket. An ordinary CPU has a data bus width of 64 bits or 32 bits using it all when communicating with memory. Control signals and power lines in the DDR SDRAM module are disposed by considering the data bus width. Memory expansion for a CPU can be done by increasing a capacity per memory module or the number of memory devices.

Memory expansion in the CPU requires increased memory channels and arrangements and connections on the main board, which result in an increase in signal and power lines, thereby making the arrangements and connections impossible.

One of the related prior arts described in US Patent Publication No. 20080222351 relates to creating a memory pool enabling a remote connection employing an optical connection in order to resolve issues such as memory expansion due to having a memory pool in a system such as a server or a desk top, a signal distortion due to a long distance between a memory and a CPU, and heat due to having a memory in a small system and its effect to other systems.

In addition, US Patent Publication No. 20090103929 relates to forming optical interconnect between memory devices and a memory controller, having an OMB (Optical Memory Bus) between the formed interface to manage them, and transmitting data and commands according to the protocol synchronized with the clock generated in the memory controller.

In addition, Korean Patent Publication No. 10-2012-0027209 relates to a method of memory expansion through optical interconnect, in which the interfaces of a CPU and a memory are not changed but data transmission of an expanded memory board is performed by optical interconnect. That is, the data of expanded memory is optically connected, but the data transmission to the CPU or memory is performed electrically.

In addition, US Patent Publication No. 20090279341 relates to communicating with memory systems and computer systems by employing Proximity Communication (P×C) between chips, and managing data through a module controller in an optical buffer chip, wherein capacitance communication is made between a memory chip and P×C.

### SUMMARY

The present invention provides a DDR SDRAM module and a method to facilitate memory expansion by restructuring the DDR SDRAM module to reduce the number of signal lines.

Specifically, the present invention enables all the necessary data and control signals for the memory module to be processed in the memory module and the processed data to be packetized to transfer optically, thus reducing the number of signal lines and facilitating the memory expansion.

However, the present invention shall by no means be restricted by the present descriptions and shall be clearly understood through the following description.

A DDR SDRAM module in accordance with an embodiment of the present invention includes: a plurality of memory chips; and a serial transceiver portion configured to serially receive first serial data which includes a control signal for the plurality of memory chips and data which is transferred from an external device, and to provide the control signal and the data included in the first serial data received serially to the plurality of memory chips.

The DDR SDRAM module in accordance with the present invention can also include a memory controller configured to transfer the serial data which includes the control signal for the plurality of memory chips and the data to the serial transceiver portion, and to control the DDR SDRAM module.

The serial transceiver portion can include: a first protocol engine portion having a predetermined first protocol engine and configured to communicate with the memory controller and provide the control signal and the data included in the first serial data to the plurality of memory chips by employing the first protocol engine; and a first serial transceiver configured to serially send second serial data generated by the first protocol engine and transfer the received first serial data to the first protocol engine portion.

The memory controller can transfer the first serial data optically through packet communication which loads the first serial data in a packet to the serial transceiver portion.

The memory controller can include: a second protocol engine portion having a predetermined second protocol engine and configured to communicate with the serial transceiver portion by employing the second protocol engine; and a second serial transceiver configured to send the first serial data generated by the second protocol engine to the serial transceiver portion and transfer the second serial data received from the serial transceiver portion to the second protocol engine portion.

The DDR SDRAM module can further include a socket having a module including the plurality of memory chips and the serial transceiver portion physically inserted therein and configured to transmit the first serial data between the serial transceiver portion and the memory controller. The socket can be a dual in-line memory module (DIMM) socket.

The socket can include: a third protocol engine having a predetermined third protocol engine portion and configured to communicate with the serial transceiver portion and the memory controller by employing the third protocol engine; and a third serial transceiver configured to transmit the first serial data by employing the third protocol engine or a serial transceiver interface configured to perform interface for transmitting the first serial data.

A method for configuring a DDR SDRAM module having a plurality of memory chips in accordance with an embodiment of the present invention includes: serially receiving a first serial data including a control signal for the plurality of memory chips and data by a serial transceiver portion; and providing the control signal and the data included in the first serial data received serially from the serial transceiver portion to the plurality of memory chips.

The method for configuring a DDR SDRAM module can further include transferring the first serial data including the control signal for the plurality of memory chips and the data to the serial transceiver portion by a memory controller controlling the DDR SDRAM module.

The method for configuring a DDR SDRAM module can further include: communicating with the memory controller by employing a predetermined first protocol engine by the serial transceiver portion; and serially sending second serial data generated by the first protocol engine to the memory controller by the serial transceiver portion. In the step of providing the control signal, the control signal and the data included in the first serial data are provided to the plurality of memory chips through the first protocol engine.

### BRIEF DESCRIPTION OF THE DRAWINGS

FIG. 1 presents examples of typical types of a conventional SDRAM module.

FIG. 2 presents an example of a data bus width from one of signals of a conventional DDR SDRAM module.

FIG. 3 presents an example of connection between a memory controller and a conventional DDR SDRAM module through DDR interface of DIMM.

FIG. 4 presents a structure of a DDR SDRAM module in accordance with an embodiment of the present invention.

FIG. 5 presents an example illustrating communication between memory chip in FIG. 4 and protocol engine portion.

FIG. 6 presents a structure of a DDR SDRAM module in accordance with another embodiment of the present invention.

FIG. 7 presents an operational flow diagram of a method for configuring a DDR SDRAM module in accordance with an embodiment of the present invention.

### DETAILED DESCRIPTION

Hereinafter, a DDR SDRAM module in accordance with an embodiment of the present invention and a method for configuring it will be described with reference to FIG. 1 to FIG. 7. A detail explanation focused on understanding actions and interactions in accordance with the present invention will be followed.

Also to describe the components of the present invention, different symbols for a same component can be used in different drawings and same symbols can be used in different drawings. However it does not mean a certain component acts differently in accordance with an embodiment nor the different components have a same function in different embodiments thus the functions of each component must be understood by the description about the component of the embodiment. FIG. 1 presents examples of typical types of a SDRAM module.

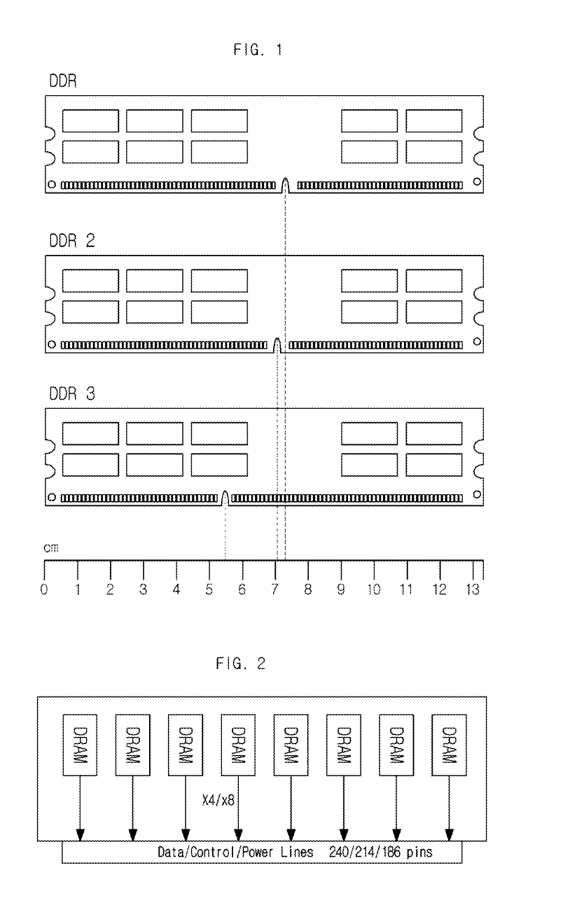

FIG. 2 presents an example of a width of data bus from one of signals of a conventional DDR SDRAM module.

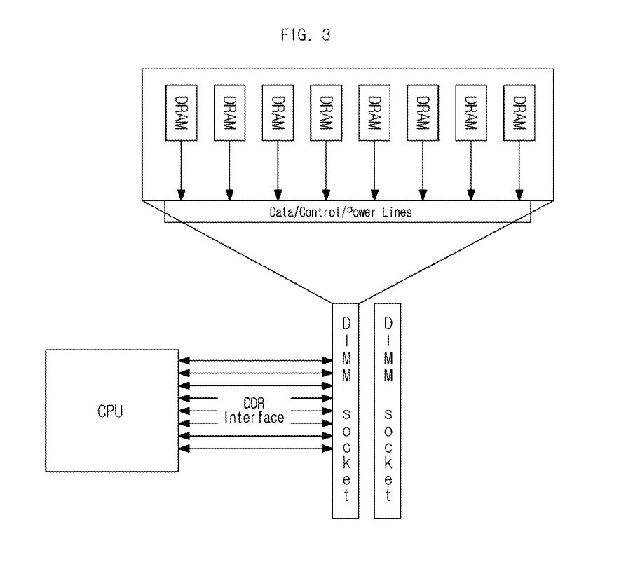

FIG. 3 presents an example of a connection between a memory controller and a conventional DDR SDRAM module through DIMM's DDR interface.

The following is the explanation about a conventional DDR SDRAM module with reference to FIG. 1 and FIG. 3.

A conventional DDR SDRAM communicates with a memory controller, for example a CPU inserted in a DIMM socket. A general CPU has a data bus width of 64 bits or 32 bits and uses it when communicating with a memory. Control signals and power lines in the conventional DDR SDRAM module are disposed considering the data bus width.

For a DDR/DDR2/DDR3 module, data buses are formed in accordance with the width of a memory controller, for example, CPU, as a memory chip put on a board as presented in FIG. 1. The buses may be seen as Table 1 according to a socket's type and DDR SDRAM's type having data and control signals therein. The maximum data transfer rate is 3.2 GT/s for DDR4.

As the conventional DDR SDRAM has time delay among data, many efforts have been put on to resolve it by employing fly-by topology along with write/read leveling technique thereby increasing the data speed. However, employing the topology and technique can not hinder the number of memory devices per memory channel being able to send and receive the data safely to and from the memory controller, here a CPU from being reduced, therefore as number of lines for transmitting signals increases, routing the lines on the main board make them have different lengths and thus creating time delay and interference among the data.

TABLE 1

| | | | Control | Power | Remark(n.c: |
|---|---|---|---|---|---|
| Type | Pin | Data bus | signal | line | no connection) |
| DIMM | 240 | 80 = 64(DQ) + | 71 | 89 | Control signal |
| | | 16(differential | | | includes n.c |
| | | DQS) | | | |
| SO-DIMM | 204 | 80 = 64(DQ) + | 49 | 75 | Control signal |
| | | 16(differential | | | includes n.c |
| | | DQS) | | | |
| Micro | 214 | 80 = 64(DQ) + | 59 | 75 | Control signal |
| DIMM | | 16(differential | | | includes n.c |
| | | DQS) | | | |

Moreover, as shown in FIG. 3, in cased of the conventional DDR SDRAM module, the entire data buses of the memory chips consist of DIMM's data buses. For example, the data bus width for a DIMM having 8×8 memory chips is 64, thus a number of pins becomes about 130˜150 by adding control signals thereto. In this case, the memory controller needs to route 130˜150 lines per CPU-memory channel for memory expansion thus creating intervention, data skew and signal integrity for a high speed DDR3 or DDR4. Recently, the number of DIMM allocated to CPU-memory channel has been reduced to 1 or 2, for such reason.

The present invention relates to increasing a number of memory devices and a changing communication method of a memory controller in a DDR SDRAM from parallel to serial enabling arrangements and connections on a main board thus facilitating memory expansion.

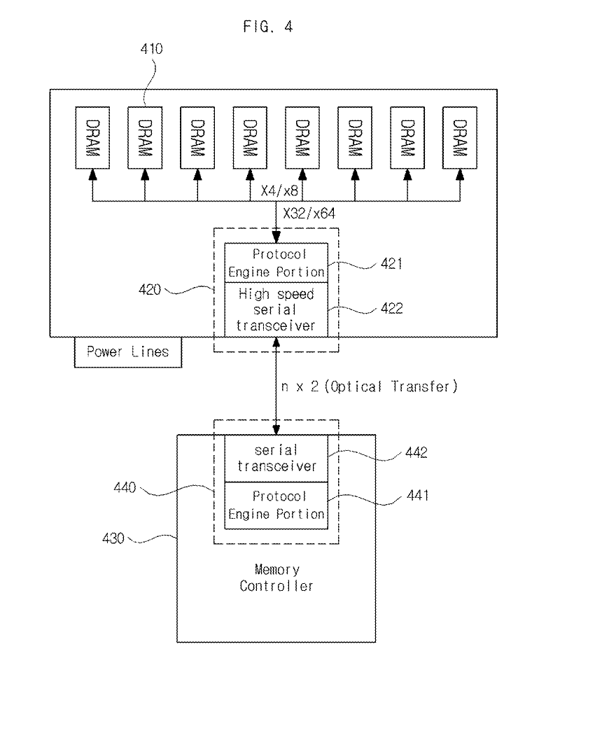

FIG. 4 presents a structure of a DDR SDRAM module in accordance with an embodiment of the present invention.

With reference to FIG. 4, the DDR SDRAM module in accordance with the present invention includes a plurality of memory chips 410, a serial transceiver portion 420 and a memory controller 430.

The plurality of memory chips 410 store data. The data are received through from the serial transceiver portion 420 by communicating with a protocol engine portion 421 in the serial transceiver portion 420. For example, data are stored using a control signal from the memory controller 430 and read by the memory controller 430.

The serial transceiver portion 420 receives first serial data in a serial way, which includes the control signal for the plurality of memory chips 410 and data from the memory controller 430, and provides the control signal and data to the plurality of memory chips 410.

Here, the serial transceiver portion 420 can receive the first serial data through packet communication with the memory controller 430 and can receive it optically from the memory controller 430.

As shown in FIG. 4, the serial transceiver portion 420 may include a first protocol engine portion 421 and a first serial transceiver 422 and also can include a serial transceiver interface (not shown).

The first protocol engine portion 421 has a predetermined first protocol engine and communicates with the memory controller 430 and the plurality of memory chips 410 by using the first protocol engine. For example, the first protocol engine portion 421 receives the first serial data transferred from the memory controller 430 by communicating with it through the first serial transceiver 422 and provides the control signal for the plurality of memory chips 410 and data which are included in the first serial data to the plurality of memory chips 410 through communicating with the plurality of memory chips 410.

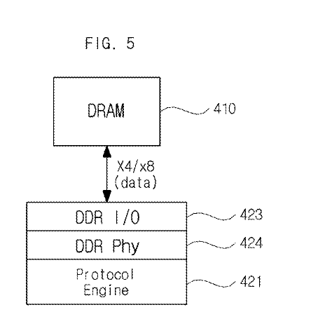

Here, the first protocol engine portion 421 is an interface for receiving the memory controller 430's command and data and sending them to a memory chip in the memory module. As shown in FIG. 5, to interface with the plurality of memory chips 410, a DDR I/O 423 and a DDR PHY 424, which are in a conventional memory controller, are mounted in the first protocol engine portion 421.

Here, the first protocol engine can serially communicate with the memory controller 430 and communicate with the plurality of memory chips 410. It also can include any other protocols related to the present invention.

In the same way, the first protocol engine portion 421 can generate second serial data including data received data from the plurality of memory chips 410 and transfer the second serial data to the memory controller 430 through the first protocol engine 421 by use of a packet communication. Here, the second serial data can be transferred optically to the memory controller 430.

The first serial transceiver 422 transfers the first serial data received serially from the memory controller 430, through optical communication, to the first protocol engine portion 421; and serially transmits the second serial data generated by the first protocol engine portion 421 to the memory controller 430 through optical communication.

Here, the data communication between the memory controller 430 and the first serial transceiver 422 is done by optical packet communication. It may be done by a serial transceiver interface (not shown). The memory controller 430 transfers the first serial data including the control signal for the plurality of memory chips 410 and data to the serial transceiver portion 420 through optical packet communication, and controls the DDR SDRAM module. The memory controller 430 in the present invention can be a CPU in a main board or separate controller for controlling only the DDR SDRAM module and more extensively can include all controllers applicable to the present invention. In the same way, the memory controller 430 also can include a serial transceiver portion 440 which includes a second protocol engine portion 441 and a second serial transceiver 442. The serial transceiver portion 440 of the memory controller 430 also can include a serial transceiver interface. The second protocol engine portion 441 has a predetermined first protocol engine and communicates with the first protocol engine portion 421 by employing the second protocol engine, and generates the first serial data including the control signal or command for the plurality of memory chips 410 and data and performs optical packet communication through the second serial transceiver 442. Certainly, the second protocol engine portion 441 receives the second serial data transferred from the first serial transceiver 422 through the second serial transceiver 442, and can extract data from the received second serial data and transfer it to the memory controller 430.

Here, even though the second protocol engine and the first protocol engine can be the same type or different type. The same type engine is preferable.

The second serial transceiver 442 transfers the second serial data received serially from the first serial transceiver 422 through optical communication to the second protocol engine portion 441 and sends serially the first serial data generated by the second protocol engine portion 441 to the first serial transceiver 422 through optical communication.

As such, according to the present invention, the data bus stays in DDR SDRAM module, not in a main board, and optical data communication by use of a serial transceiver and other serial units enables high speed communication and serial packet communication to reduce the number of buses. That is, only n×2 number of data buses for sending and receiving are needed between a memory controller and memory chips.

Here. n is a number of bus set decided by a optical transceiver transfer rate and the data bandwidth of a DDR SDRAM. For example, if the transceiver transfer rate is 10 Gbps and for and the data bandwidth is 10 Gbps, then n is ‘1’. If the transceiver rate is 100 Gbps and the data bandwidth is 100 Gbps, then n is ‘1’, and if the transceiver rate is 10 Gbps and the data bandwidth is 100 Gbps, then n becomes ‘10’.

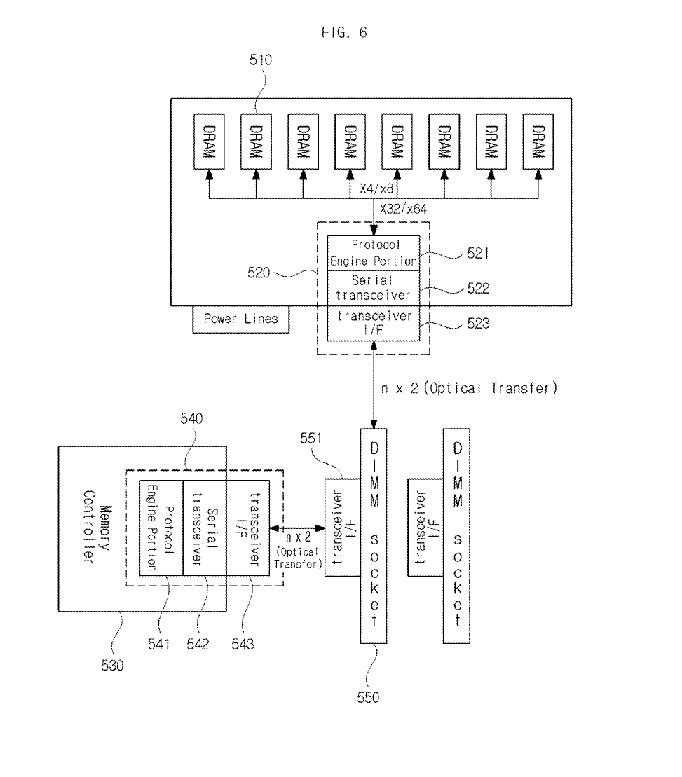

The DDR SDRAM module in accordance with the present invention can use a socket between the memory controller and the plurality of memory chips, as presented in FIG. 6.

FIG. 6 presents a structure of a DDR SDRAM module in accordance with another embodiment of the present invention.

The DDR SDRAM module in accordance with the present invention includes a plurality of memory chips 510, a serial transceiver portion 520, and a memory controller 530.

The description about the plurality of memory chips 510 is omitted because it is the same as the plurality of memory chips 410 in FIG. 4

The serial transceiver portion 520 includes a first protocol engine portion 521, a first serial transceiver 522, and a first serial transceiver interface 523.

The first protocol engine portion 521 has a predetermined first protocol engine and communicates with the memory controller 530 and the plurality of memory chips 510 by employing the first protocol engine. For example, the first protocol engine 521. For example, the first protocol engine portion 521 receives the first serial data transferred from the memory controller 530 by communicating with it through the first serial transceiver 522 and provides the control signal for the plurality of memory chips 510 and data which are included in the first serial data to the plurality of memory chips 510 through communicating with the plurality of memory chips 510

Here, the first protocol engine can serially communicate with the socket 550 and communicate with the plurality of memory chips 510, and also can include any other protocol related to the present invention. In the same way, the first protocol engine portion 521 can generate second serial data including data received from the plurality of memory chips 510 and transfer the second serial data to the socket 550 optically through the first serial transceiver 522 through a packet communication. The first serial transceiver 522 transfers the first serial data received serially from the memory controller 530 through optical communication to the first protocol engine portion 521; and sends the second serial data generated by the first protocol engine portion 521 to the socket 550 serially through optical communication.

Here, the data transmit between the socket 550 and the first serial transceiver 522 is done by optical packet communication.

The first serial transceiver interface 523 interfaces the first serial data received at the first serial transceiver 522 and the second serial data transferring from the first serial transceiver 522.

The memory controller 530 transfers the first serial data which including the control signal for the plurality of memory chips 410 and data to the socket 550 through optical packet communication, and controls the DDR SDRAM module. In the same way, the memory controller 530 also can include a serial transceiver portion 540 which includes a second protocol engine portion 541, a second serial transceiver 542, and the second serial transceiver interface 543.

The second protocol engine portion 541 has a predetermined second protocol engine and communicates with the socket 550 by employing the second protocol engine, and generates the first serial data which including the control signal or command for the plurality of memory chips 510 and data and performs optical packet communication through the second serial transceiver 542. Certainly, the second protocol engine portion 541 receives the second serial data transferred from the socket 550 through the second serial transceiver 542, and can extract data from the received second serial data and transfer it to the memory controller 530.

Here, even though the second protocol engine and the first protocol engine can be the same or different engine, it is preferable to use the same engine.

The second serial transceiver 542 transfers the second serial data received serially from the socket 550 through optical communication to the second protocol engine portion 541, and sends the first serial data generated by the second protocol engine portion 541 to the socket 550 serially through optical communication.

The second serial transceiver interface 543 interfaces the second serial data received at the second serial transceiver 542 and the first serial data transferring from the second serial transceiver 542.

The socket 550 where the module having the plurality of memory chips 510 and the serial transceiver portion 520 is physically inserted therein transmits the first serial data and the second serial data between the serial transceiver portion 520 and the memory controller 530.

Here, data communication between the socket 550 and the serial transceiver portion 520, and the socket 550 and the memory controller 530 can be done by optical packet communication, and the socket 550 can include a DIMM socket.

The socket in accordance with the present invention can be only a serial transceiver interface 551, but can include a serial transceiver, if necessary.

The socket 550 can have a third protocol engine portion (not shown), a third serial transceiver (not shown) and a third serial transceiver interface (not shown). The third protocol engine portion can include a predetermined third protocol engine as the same case as the first protocol engine portion 521 and the second protocol engine portion 541.

Here, the third protocol engine can be the same or different with the first protocol engine and the second protocol engine.

The third protocol engine portion performs optical communication with the serial transceiver portion 520 and the memory controller 530 by employing of the third protocol engine.

The third serial transceiver receives the first serial data or the second serial data through optical communication and sends it to the serial transceiver portion 520 and the memory controller 530 through the third protocol engine portion.

The third serial transceiver interface interfaces for the first serial data or for the second serial data transferring from or to the third serial transceiver.

As such, a DDR SDRM module in accordance with the present invention can include a DIMM socket where a memory chip can be physically inserted therein. By using a DDR SDRAM module having serial communication, a number of buses connected with the DIMM socket and between the DIMM socket and a memory controller can be reduced. The number of pins in a board according to socket types in accordance with the present invention can be as Table. 2.

TABLE 2

| | | | | |
|---|---|---|---|---|
| | | Data and control | | |
| Type | Data bus | signal | Power line | Remark |

| | | | |
|---|---|---|---|
| DIMM | 80 −> nx2 | Included in | Varies on board |
| | (Tx/Rx) | protocol | |
| SO-DIMM | 80 −> nx2 | Included in | Varies on board |
| | (Tx/Rx) | protocol | |
| Micro | 80 −> nx2 | Included in | Varies on board |
| DIMM | (Tx/Rx) | protocol | |

As shown in the Table 2, the DDR SDRM module in accordance with the present invention requires a number of buses as less as only for control signals and data transmission due to the serial packet communication thus enabling to reduce the number of signal lines thereby facilitating memory expansion.

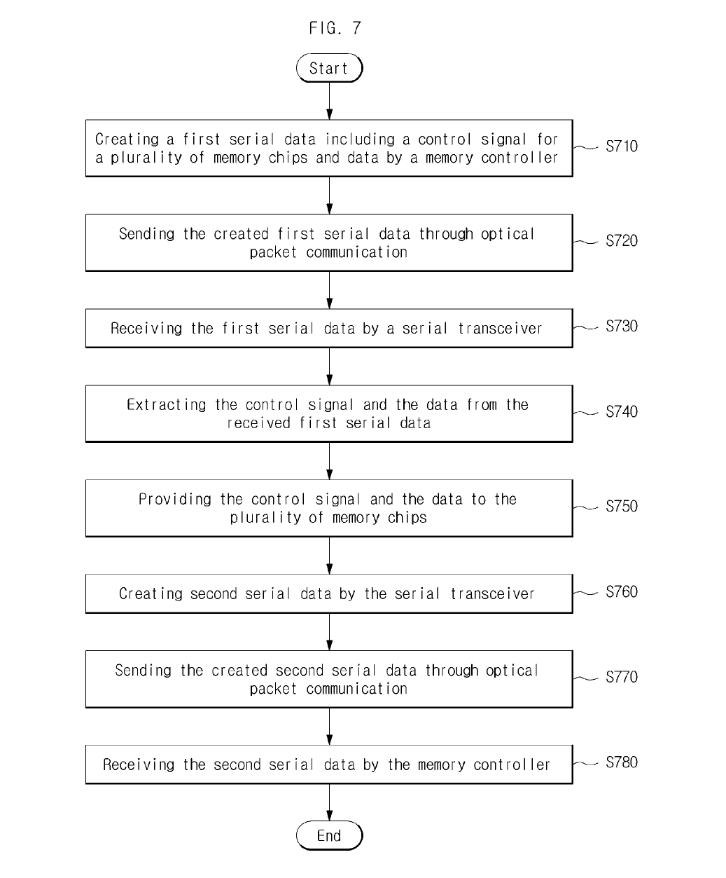

FIG. 7 presents an operational flow diagram of a method for configuring a DDR SDRAM module in accordance with an embodiment of the present invention.

With reference to FIG. 7, a memory controller generates first serial data which including a control signal, ‘read’ or ‘write’, for the plurality of the memory chips and data, and sends it through optical packet communication S710, S720.

Here, the memory controller can communicate by employing the protocol engine therein and the first serial data can be generated by the protocol engine. The memory controller can perform optical communication directly between the plurality of the memory chips and the serial transceiver for transmitting the first serial data. However, when the module having the plurality of memory chips is physically in the DIMM socket, the optical communication can be done by the DIMM socket. In this case, the DIMM socket should be able to perform serial communication and optical communication.

When, the serial transceiver receives the first serial data through optical packet communication from the memory controller, the serial transceiver extracts the control signal for the plurality of memory chips and data in the received first data and provides them to the plurality of memory chips S730, S750.

The serial transceiver can receive the first serial data either directly from the memory controller or from the DIMM socket.

Here, the serial transceiver can include a protocol engine for the communication or a serial transceiver for high speed serial communication.

The DIMM socket also has to have components for optical communication as well as high speed serial communication. The serial transceiver provides a control signal or control command and data to the plurality of the memory chips, and transfers the second serial data stored in the plurality of the memory chips by the protocol engine to the memory controller by employing optical packet communication. In the same way, the second serial data can be transferred to the memory controller through the DIMM socket. The memory controller receives the second serial data by optical communication and reads the data in the second serial data S780.

According to the present invention, a DDR SDRM module can process necessary data and control signals therein and packetize and optically transfer the processed data, thereby reducing the number of signal lines and facilitating memory addition and extension.

Therefore, according to the present invention, memory can be easily added and a memory rack can be configured.

In addition, it is easy to arrange and connect memory related signal lines in a main board.

Furthermore, the use of a protocol engine can supplement signal integrity by re-request of data when the data error occurs and allow memory share among multiple CPUs and multiple servers.

Although it is described above that all elements constituting the embodiment of the present invention are combined or operated in combination, the present invention is not necessarily limited to what has been described herein. That is, two or more of the elements constituting the embodiment of the present invention can be selectively combined with one another or operated in combination with one another as long as such combination is within the object of the present invention. Moreover, although it is possible that every element is realized as its own individual hardware, it is also possible that some or all of the elements are selectively combined with one another to be realized as a computer program having a program module that performs the combined some or all functions in one or more hardware. Moreover, the embodiment of the present invention can be realized by having said computer program stored in computer-readable media, such as USB memory, CD disk, flash memory, etc., and read and executed by a computer. The computer-readable media can also include magnetic recording media, optical recording media, carrier wave media, etc.

The description so far is only an example of technical ideas of this present invention, so various permutations, modification, or replacement are possible for people who work in the technical area of the present invention as long as not distracting the original intention of the present invention. Therefore the embodiment disclosed in the present invention and the attached diagrams are not for restricting the technical ideas of the present invention but for explaining and the technical ideas of the present invention are not to be restricted by the embodiment and the attached diagrams. The protected scope of the present invention shall be understood by the scope of claims below, and all technical ideas which reside in the scope of claims shall be included in the rights of the present invention.

What is claimed is:

1. A DDR SDRAM module comprising:
a plurality of memory chips; and
a serial transceiver portion configured to serially receive first serial data including a control signal and data transferred from outside for the plurality of memory chips and to provide the control signal and the data included in the serially received first serial data to the plurality of memory chips.

2. The DDR SDRAM module of claim 1, further comprising a memory controller configured to transfer the first serial data including the control signal and the data for the plurality of memory chips to the serial transceiver portion and to control the DDR SDRAM module.

3. The DDR SDRAM module of claim 2, wherein the serial transceiver portion comprises:
a first protocol engine portion having a predetermined first protocol engine and configured to communicate with the memory controller and to provide the control signal and the data included in the first serial data to the plurality of memory chips by use of the first protocol engine; and
a first serial transceiver configured to serially send second serial data generated by the first protocol engine and to transfer the received first serial data to the first protocol engine portion.

4. The DDR SDRAM module of claim 2, wherein the memory controller is configured to transfer the first serial data optically to the serial transceiver portion through packet communication which loads the first serial data in a packet.

5. The DDR SDRAM module of claim 2, wherein the memory controller comprises:
a second protocol engine portion having a predetermined second protocol engine and configured to communicate with the serial transceiver portion by use of the second protocol engine; and
a second serial transceiver configured to send the first serial data generated by the second protocol engine to the serial transceiver portion and to transfer the second serial data received from the serial transceiver portion to the second protocol engine portion.

6. The DDR SDRAM module of claim 2, further comprising a socket having a module including the plurality of memory chips and the serial transceiver portion physically installed therein and configured to transmit and receive the first serial data between the serial transceiver portion and the memory controller.

7. The DDR SDRAM module of claim 6, wherein the socket is a dual in-line memory module (DIMM) socket.

8. The DDR SDRAM module of claim 6, wherein the socket comprises:
a third protocol engine portion having a predetermined third protocol engine and configured to communicate with the serial transceiver portion and the memory controller by use of the third protocol engine; and
a third serial transceiver configured to transmit and receive the first serial data by use of the third protocol engine.

9. The DDR SDRAM module of claim 6, wherein the socket comprises a serial transceiver interface configured to perform interface for transmitting and receiving the first serial data.

10. A method for configuring a DDR SDRAM module having a plurality of memory chips, the method comprising:
receiving first serial data serially from a serial transceiver portion, the first serial data including a control signal and data for the plurality of memory chips; and
providing the control signal and the data included in the first serial data received serially from the serial transceiver portion to the plurality of memory chips.

11. The method of claim 10, further comprising
transferring the first serial data including the control signal and the data for the plurality of memory chips to the serial transceiver portion by a memory controller controlling the DDR SDRAM module.

12. The method of claim 11, further comprising:
communicating with the memory controller by use of a predetermined first protocol engine by the serial transceiver portion; and
serially sending second serial data generated by the first protocol engine to the memory controller by the serial transceiver portion,
wherein in the step of providing the control signal and the data, the control signal and the data included in the first serial data are provided to the plurality of memory chips through the first protocol engine.

13. The method of claim 11, wherein in the step of transferring the first serial data, the first serial data is optically transferred to the serial transceiver portion through packet communication which loads the first serial data in a packet.

14. The method of claim 11, wherein the transferring of the first serial data comprises:
communicating with the serial transceiver portion by use of a predetermined second protocol engine; and
transferring the first serial data generated by the second protocol engine to the serial transceiver portion.

15. The method of claim 11, wherein in the step of transferring the first serial data, the first serial data is transferred to the serial transceiver portion through a dual in-line memory module (DIMM) socket in which a module including the plurality of memory chips and the serial transceiver portion are physically installed.
